(19) United States
(12) Patent Application Publication
(10) Pub. No.: US 2009/0308652 A1
(43) Pub. Date: Dec. 17, 2009

(54) PACKAGE SUBSTRATE HAVING DOUBLE-SIDED CIRCUITS AND FABRICATION METHOD THEREOF

(75) Inventor: Chao-Wen Shih, Hsin-chu (TW)

Correspondence Address: SCHMEISER OLSEN & WATTS, 18 E UNIVERSITY DRIVE, SUITE # 101, MESA, AZ, 85201, US

(73) Assignee: PHOENIX PRECISION TECHNOLOGY CORPORATION, Hsin-chu (TW)

(21) Appl. No.: 12/476,977

(22) Filed: Jun. 2, 2009

(30) Foreign Application Priority Data
Jun. 3, 2008 (TW) 097120551

(51) Int. Cl. H05K 1/11; H01R 12/04

(52) U.S. Cl. 174/264; 174/262

(57) ABSTRACT

A package substrate having double-sided circuits and a method of manufacturing the same are proposed. The package substrate includes a core board having a plated through hole, a plurality of first electrical contact pads, and a first solder mask layer formed on the core board. A first wiring layer and a second wiring layer are disposed on two opposite surfaces of the core board, respectively, and electrically connected to the plated through hole. A portion of the first wiring layer is exposed from a first opening formed in the first solder mask layer. The first electrical contact pads are disposed on the exposed portion of the first wiring layer. The top surface of the first electrical contact pads is higher than that of the first wiring layer to thereby allow a semiconductor chip to be mounted on the electrical contact pads for improving electrical connection.

### FIELD OF THE INVENTION

The present invention relates to package substrates, and more particularly, to a package substrate having double-sided circuits.

### DESCRIPTION OF RELATED ART

In order to satisfy the requirements of high integration and miniaturization of the semiconductor package, multi-layer boards have emerged for the package substrate to carry semiconductor chips despite limited space. It allows an expansion of utilizable circuit layout on the package substrate by the technique of interlayer connection so that it meets the needs of integrated circuits with a high density. However, as the number of layers of a multi-layer board increases, paths of electric current, and thickness of the substrate increase to the detriment of miniaturization and high-speed transmission. Therefore, a package substrate having double-sided circuits has been developed to reduce the number of layers of a multi-layer board.

FIGS. 1A to 1G are cross-sectional diagrams showing a conventional package substrate having double-sided circuits and a fabrication method thereof.

Referring to FIG. 1A, a core board 10 has opposing first and second surfaces 10a, 10b each having a first metallic layer 101 formed thereon. Moreover, a through-hole 100 is formed to penetrate the core board 10 and the first metallic layer 101. Referring to FIG. 1B, a conductive layer 101 is formed on the first metallic layer 101 and on the wall of the through-hole 100. Referring to FIG. 1C, a resist layer 12 is formed on the conductive layer 11, and a plurality of opening portions 120 are formed in the resist layer 12 to expose the through-hole 100 and a portion of the conductive layer 11. Referring to FIG. 1D, a second metallic layer 13 is formed in the opening portions 120, and a plated through hole 131 is formed in the through-hole 100, respectively, by plating, using the conductive layer 11 as a path of the plating process. Referring to FIG. 1E, the plating process is followed by removing the resist layer 12, the conductive layer 11 being covered by the resist layer 12, and the first metallic layer 101. Then, first and second wiring layers 13a and 13b are formed by etching the first surface 10a and the second surface 10b for electrical connection with the plated through hole 131. Besides, a plurality of first and second electrical contact pads 132a, 132b are disposed in the first wiring layer 13a and the second wiring layers 13b respectively. Referring to FIG. 1F, first and second solder mask layers 14a and 14b are formed on the first and second surfaces 10a, 10b, and the first and second wiring layers 13a, 13b. Moreover, a plurality of first and second apertures 140a, 140b are formed in the first and second solder mask layers 14a and 14b, respectively, so as for the first and second electrical contact pads 132a, 132b to be exposed from the first and second apertures 140a, 140b, respectively. Lastly, a surface treatment layer 15 is provided on each of the first and second electrical contact pads 132a, 132b as shown in 1G.

However, as the interspacing of each of the electrical contact pads and the area occupied by the electrical contact pads are becoming lesser, the first apertures 140a of the first solder mask layer 14a decrease in size. As a result, the contact area between the first electrical contact pads 132a and solder bumps (not shown in the drawings) coupled to the semiconductor chip decreases. With the solder bumps being formed by screen printing, the average allowable tolerance in volume and height of the solder bumps are difficult to control, Therefore, bonding of the first electrical contact pads 132a and the solder bumps is weak, which further affects electrical connection yield of the semiconductor chip. For example, in case of great average volume and height of solder bumps, contacts are likely to be bridged, thus resulting in a short circuit. On the other hand, small average volume and height of solder bumps is unfavorable to the follow-up underfill process of packaging.

Additionally, high allowable tolerance in height of solder bumps causes an unbalanced contact stress due to poor coplanarity, and in consequence the semiconductor chip is likely to crack. Therefore, the aforesaid package structure fails to meet the requirements for a high I/O chip with a high layout density.

What is more, the manufacturing process of the plated through hole 131 includes performing plating to enable electrical conduction (as shown in FIG. 1D), as well as etching a metal layer so as for the metal layer to be thinned down to a desired thickness (as shown in FIG. 1E). However, in order to achieve fine spacing between the circuits, thickness of a layer of metal plated to form the plated through hole 131 has to match circuit thickness, and thus an overly thin layer of metal is likely to be plated to form the plated through hole 131, or even etching-away can happen.

Hence, it is imperative to provide a package structure with an embedded semiconductor chip so as to solve the above-mentioned technical issues.

### SUMMARY OF THE INVENTION

In light of the drawbacks of the prior art, it is an objective of the present invention to provide a package substrate having double-sided circuits with a high layout density.

Another objective of the present invention is to provide a package substrate having double-sided circuits to enhance the electrical connection yield.

Yet another objective of the present invention is to provide a package substrate having double-sided circuits that can avoid an insufficient thickness of a plated through hole.

To achieve the above-mentioned or other objectives, the present invention provides a package substrate having double-sided circuits, comprising: a core board having a first surface, an opposing second surface, and a plated through hole, the plated through hole penetrating the first and second surfaces and having a connection ring extending to the first and second surfaces; first and second wiring layers formed on the first surface and the second surface of the core board, respectively, and electrically connected to the plated through hole; a plurality of first electrical contact pads disposed on a top surface of a portion of the first wiring layer, allowing a top surface of the first electrical contact pads to be higher than the top surface of the portion of the first wiring layer, wherein the top surface of the portion of the first wiring layer having the first electrical contact pads disposed thereon is higher than the top surface of the portion of the first wiring layer not having the first electrical contact pads disposed thereon; a first solder mask layer formed on the first surface of the core board and the first wiring layer to thereby allow the first electrical contact pads to be exposed from the first solder mask layer; and a second solder mask layer formed on the second surface of the core board and the second wiring layer.

The core board of the package substrate is an insulating board. The plated through hole is of a hollow shape and is filled in full with the first and second solder mask layers. Alternatively, the plated through hole is of a solid shape and is filled in full with a metallic material by plating. The first wiring layer comprises first and second metallic layers, and the second wiring layer comprises the first and second metallic layers, allowing the first electrical contact pads to be disposed on the second metallic layer.

Further, the first solder mask layer has a plurality of first apertures for exposing the first electrical contact pads, respectively, wherein the diameter of the first apertures is larger than or equal to the width of each of the first electrical contact pads. Alternatively, the first solder mask layer has an opening for exposing the first electrical contact pads. A surface treatment layer is disposed on the first electrical contact pads.

The top surface of the first solder mask layer is lower than top surfaces of the first electrical contact pads. The top surface of the connection ring is flush with the top surface of the first wiring layer not having the first electrical contact pads disposed thereon.

The present invention further provides a package substrate having double-sided circuits, comprising: a core board having a first surface, an opposing second surface, and a plated through hole, the plated through hole penetrating the first and second surfaces and having a connection ring extending to the first and second surfaces; first and second wiring layers formed on the first surface and the second surface of the core board, respectively, and electrically connected to the plated through hole, wherein a portion of the first wiring layer has a plurality of first electrical contact pads disposed thereon, allowing a top surface of the first electrical contact pad to be higher than a top surface of the first wiring layer and a top surface of the connection ring to be higher than the top surface of the first wiring layer; a first solder mask layer formed on the first surface of the core board and the first wiring layer so as for the first electrical contact pads to be exposed from the first solder mask layer; and a second solder mask layer formed on the second surface of the core board and the second wiring layer.

The core board of package substrate is an insulating board. The plated through hole is of a hollow shape and is filled in full with the first and second solder mask layers. The plated through hole is of a solid shape and is filled in full with a metallic material by plating. The first wiring layer and the first electrical contact pads are formed from first and second metallic layers, and the second wiring layer is formed from the first and second metallic layers.

The first solder mask layer has a plurality of first apertures for exposing the first electrical contact pads, respectively. Alternatively, the first solder mask layer has an opening for exposing the first electrical contact pads. A surface treatment layer is disposed on the first electrical contact pads.

The top surface of the first electrical contact pads is flush with the top surface of the connection ring.

Therefore, a package substrate having double-sided circuits and a fabrication method thereof are provided by the present invention by the design that a top surface of a plurality of first electrical contact pads is higher than the top surface of the first wiring layer. In contrast to prior art, the present invention provides a plurality of first electrical contact pads for replacing solder bumps so as to dispense with the solder bumps otherwise necessary for the prior art. Moreover, the average values and allowable tolerances in volume and height of the first electrical contact pads are better controllable, thereby being able to achieve an increased layout density and to enhance the electrical connection yield. Also, an etching stop layer is formed on a plated through hole; or instead, a plated through hole is configured to be of a solid shape. In so doing, it is feasible to avoid an insufficient thickness of a plated through hole which might otherwise be the case when etching the plated through hole.

### BRIEF DESCRIPTION OF DRAWINGS

FIGS. 1A to 1G are cross-sectional diagrams showing a conventional package substrate having double-sided circuits and a fabrication method thereof;

FIGS. 2A to 2K are cross-sectional diagrams showing a package substrate having double-sided circuits and a fabrication method thereof according to a first embodiment of the present invention, wherein FIGS. 2J′ and 2J″ each illustrate an alternative embodiment of the package substrate and the fabrication method thereof shown in FIG. 2J;

FIGS. 3A to 3H are cross-sectional diagrams showing a package substrate having double-sided circuits and a fabrication method thereof according to a second embodiment of the present invention; wherein FIGS. 3G′ and 3G″ each illustrate an alternative embodiment of the package substrate and the fabrication method thereof shown in FIG. 3G; and

FIGS. 4A to 4H are cross-sectional diagrams showing a package substrate having double-sided circuits and a fabrication method thereof according to a third embodiment of the present invention; wherein FIGS. 4G′ and 4G″ each illustrate an alternative embodiment of the package substrate and the fabrication method thereof shown in FIG. 4G.

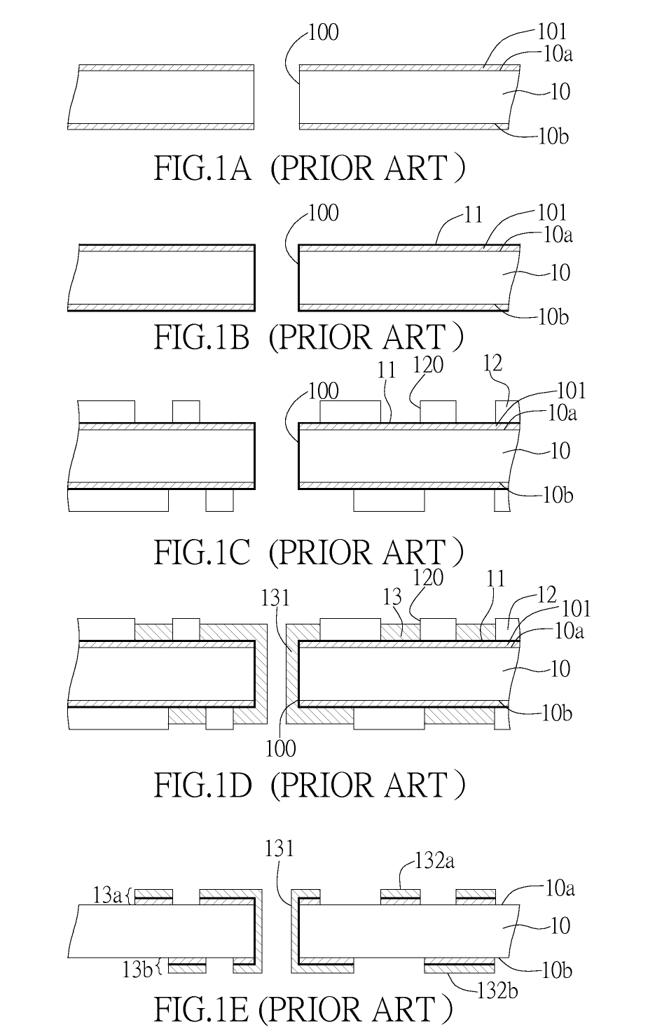

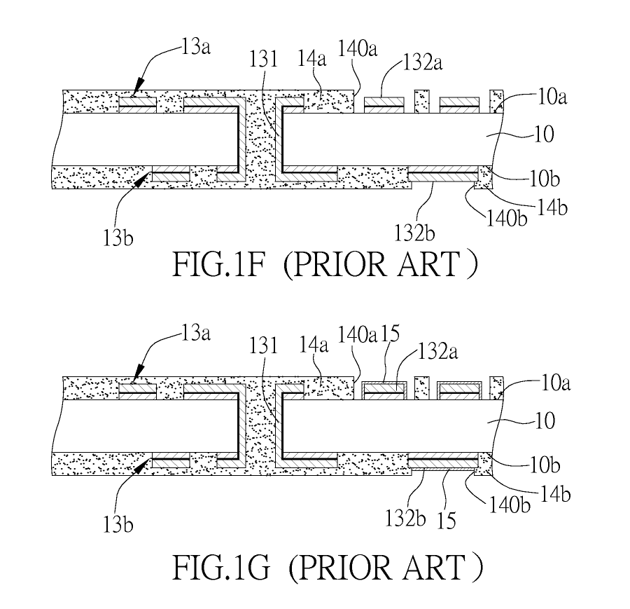

### DETAILED DESCRIPTION OF PREFERRED EMBODIMENTS

The following embodiments are provided to illustrate the disclosure of the present invention, these and other advantages and effects can be apparent to those ordinarily skilled in the art after reading the specification.

### First Embodiment

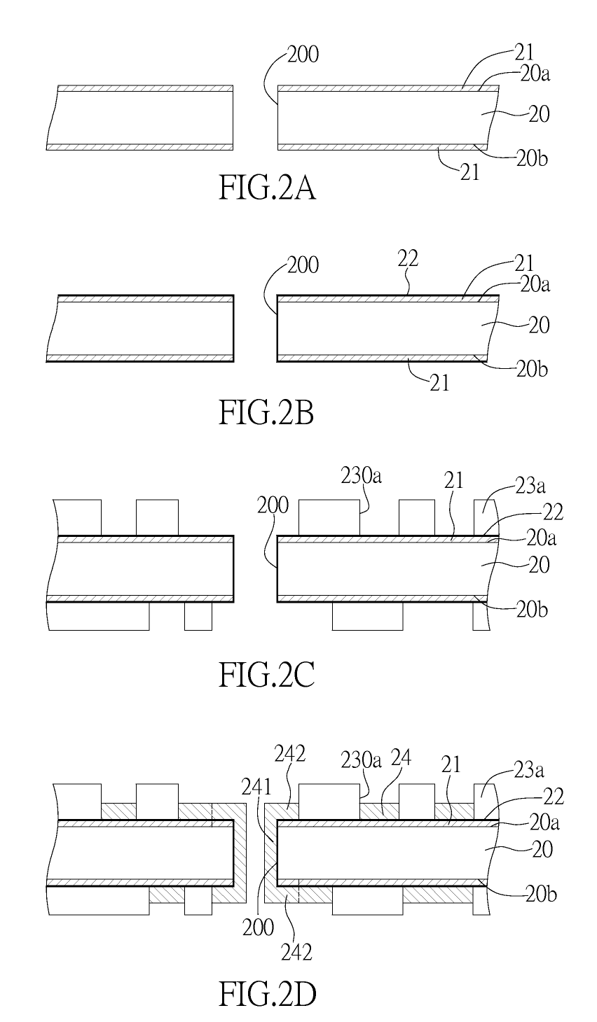

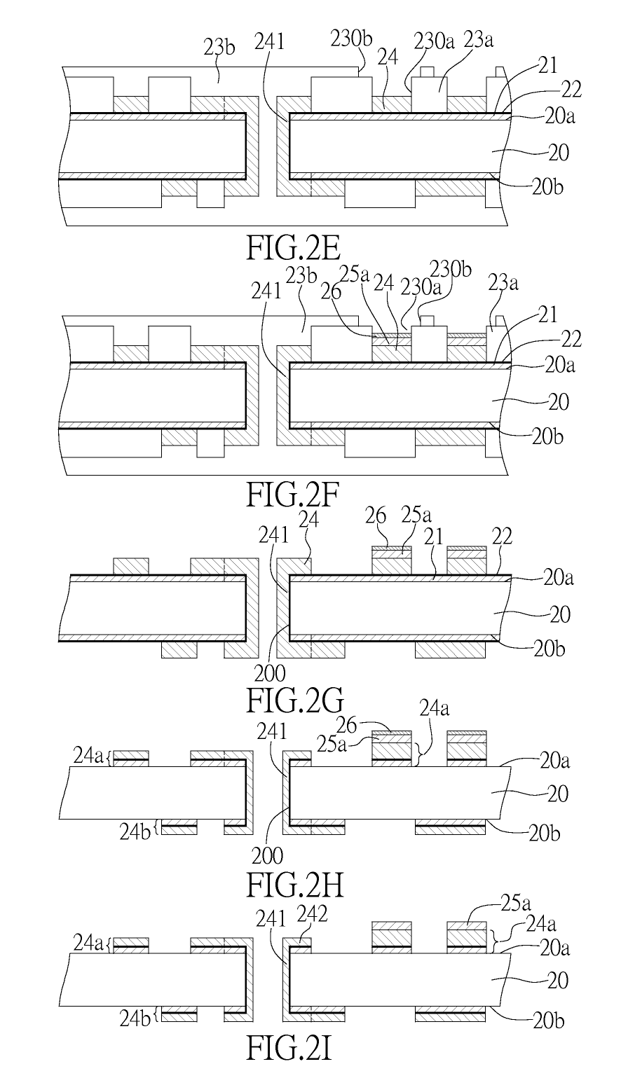

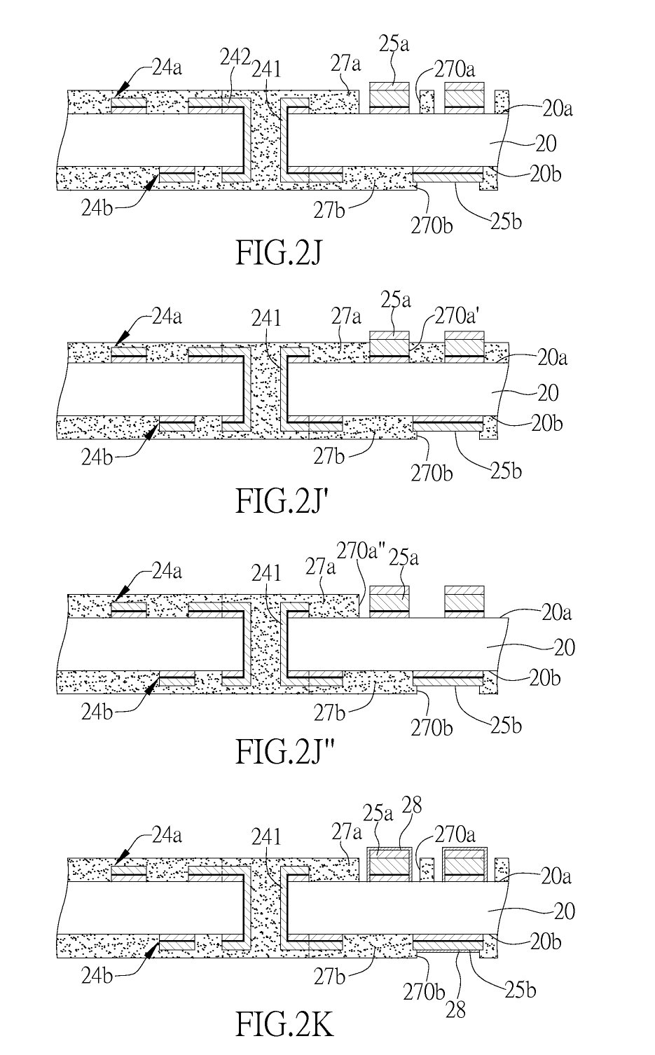

FIGS. 2A to 2K are cross-sectional diagrams showing a package substrate having double-sided circuits and a fabrication method thereof according to a first embodiment of the present invention.

Referring to FIG. 2A, a core board 20 which functions as an insulating board is provided, and the core board 20 has a first surface 20a and a second surface 20b opposing each other. As shown in the drawing, a first metallic layer 21 is formed on the first and second surfaces 20a, 20b, and a through-hole 200 is formed to penetrate the first metallic layer 21 and the first and second surfaces 20a, 20b.

Referring to FIG. 2B, a conductive layer 22 is formed on the first metallic layer 21 and walls of the through-hole 200. The conductive layer 22 is mainly used as a path of electric current required by a subsequent metal-plating process (to be described below). The conductive layer 22 is made of a metal or an alloy, or comprises a plurality of deposited metallic layer. For example, the conductive layer 22 is made of one selected from the group consisting of copper (Cu), tin (Sn), nickel (Ni), chromium (Cr), titanium (Ti), copper-chromium (Cu—Cr) alloy, and tin-lead (Sn—Pb) alloy, and is fabricated by sputtering coating, evaporation deposition, electroless plating, or chemical deposition.

Referring to 2C, a first resist layer 23a which is a dry film resist or a liquid resist is formed on the conductive layer 22 by printing, spin coating or laminating, and then the first resist layer 23a thus formed is patterned by exposure, development, and etc. Later, a plurality of first opening portions 230a are formed in the first resist layer 23a so as to expose the walls of the through-hole 200 and a portion of the conductive layer 22 on the first metallic layer 21.

Referring to FIG. 2D, a second metallic layer 24 is plated to the first opening portions 230a of the first resist layer 23a via the conductive layer 22, and then a metallic material is plated to the walls of the through-hole 200 so as for a plated through hole 241 to be formed in the through-hole 200. As shown in the drawing, the plated through hole 241 extends to the first surface 20a and the second surface 20b to form a connection ring 242 thereon, wherein the through-hole 200 is not plated with metal fully so that the plated through hole 241 is of a hollow shape.

Referring to FIG. 2E, a second resist layer 23b is disposed on the second metallic layer 24, the plated through hole 241, the connection ring 242, and the first resist layer 23a, wherein a plurality of second opening portions 230b are formed in the second resist layer 23b so as to expose a portion of the second metallic layer 24 on the first surface 20a.

Referring to FIG. 2F, a plurality of first electrical contact pads 25a are formed on the exposed second metallic layer 24 by plating, and then an etching stop layer 26 is formed on each of the first electrical contact pads 25a by plating.

Referring to FIG. 2G, the first resist layer 23a and the second resist layer 23b are removed so as to expose the plated through hole 241, the connection ring 242, a portion of the second metallic layer 24, and a portion of the conductive layer 22.

Referring to FIG. 2H, an exposed portion of the second metallic layer 24 and the connection ring 242 on the first surface 20a and the second surface 20b are thinned down by etching. Further, the conductive layer 22 and the first metallic layer 21 covered with the conductive layer 22 are removed to form on the first and second surfaces 20a, 20b a first wiring layer 24a and a second wiring layer 24b electrically connected to the plated through hole 241 and allow a top surface of the connection ring 242 to be flush with a top surface of the first wiring layer 24a, wherein the first electrical contact pads 25a are not disposed on the top surface of the first wiring layer 24a.

Next, FIG. 2I shows the steps of removing the etching stop layer 26 to expose the first electrical contact pads 25a therefrom, wherein a top surface of each of the first electrical contact pads 25a is not only higher than that of the first wiring layer 24a, but higher than that of the connection ring 242.

Referring to FIG. 2J, a first solder mask layer 27a is formed on the first wiring layer 24a and the first surface 20a of the core board 20, and a second solder mask layer 27b is formed on the second wiring layer 24b and the second surface 20b of the core board 20. The plated through hole 241 is of a hollow shape and is filled in full with the first solder mask layer 27a and the second solder mask layers 27b. Further, the first solder mask layer 27a has a plurality of first apertures 270a formed therein for exposing the first electrical contact pads 25a, respectively, and the second solder mask layer 27b has a plurality of second apertures 270b formed therein for exposing a portion of the second wiring layer 24b so as for the exposed portion of the second wiring layer 24b to function as a plurality of second electrical contact pads 25b.

In the meanwhile, a top surface of each of the first electrical contact pads 25a is lower than that of the first solder mask layer 27a in a general embodiment; alternatively, in the present embodiment, a top surface of each of the first electrical contact pads 25a is higher than that of the first solder mask layer 27a, allowing the diameter of each of the first apertures 270a to be greater than the width of each of the first electrical contact pads 25a.

Referring to FIGS. 2J′ as well as 2J″, there are various methods for exposing the first electrical contact pads 25a from the first solder mask layer 27a. For example, the diameter of each of the first apertures 270a′ is equal to the width of each of the first electrical contact pads 25a as shown in FIG. 2J′; alternatively, the first solder mask layer 27a has an opening 270a″ for exposing all of the first electrical contact pads 25a as shown in FIG. 2J″.

Referring to FIG. 2K, a surface treatment layer 28 is formed on the exposed portion of the first wiring layer 24a and each of the first electrical contact pads 25a and second electrical contact pads 25b, wherein the surface treatment layer 28 is made of an alloy comprising at least a metal selected from the group consisting of tin (Sn), lead (Pb), silver (Ag), copper (Cu), zinc (Zn), bismuth (Bi), nickel (Ni), palladium (Pd), and gold (Au), nickel/gold (Ni/Au), electroless nickel and immersion gold (EN/IG), nickel/palladium/gold (Ni/Pd/Au), or organic solderability preservatives (OSP).

The present invention provides a package substrate having double-sided circuits, comprising: the core board 20 having the first surface 20a and the second surface 20b opposing each other; the plated through hole 241 formed to penetrate the core board 20 and the first and second surfaces 20a, 20b of the core board 20 and provided with the connection ring 242 extended to the first surface 20a and the second surface 20b; the first and second wiring layers 24a, 24b formed on the first and second surfaces 20a, 20b of the core board 20, respectively, and electrically connected to the plated through hole 241; the plurality of first electrical contact pads 25a disposed on the top surface of a portion of the first wiring layer 24a so as for the top surface of each of the first electrical contact pads 25a to be higher than the top surface of the first wiring layer 24a, wherein the top surface of a portion of the first wiring layer 24a having the first electrical contact pads 25a disposed thereon is higher than the top surface of a portion of the first wiring layer 24a not having the first electrical contact pads 25a disposed thereon; the first solder mask layer 27a formed on the first wiring layer 24a and the first surface 20a of the core board 20; and the second solder mask layer 27b formed on the second wiring layer 24b and the second surface 20b of the core board 20.

The core board 20 functions as an insulating board. The first wiring layer 24a comprises the first metallic layer 21, the second metallic layer 24, and the conductive layer 22. The first electrical contact pads 25a are formed on the second metallic layer 24. Likewise, the second wiring layer 24b comprises the first metallic layer 21, the second metallic layer 24, and the conductive layer 22.

The top surface of each of the first electrical contact pads 25a is higher than the top surface of the first solder mask layer 27a. The top surface of the connection ring 242 is flush with the top surface of a portion of the first wiring layer 24a not having the first electrical contact pads 25a disposed thereon.

The plated through hole 241 is of a hollow shape and is filled in full with the first and second solder mask layers 27a, 27b; alternatively, the plated through hole 241 is of a solid shape and is filled in full with a metallic material.

The first solder mask layer 27a has a plurality of first apertures 270a formed therein for exposing the first electrical contact pads 25a, respectively. Each of the first apertures 270a is of diameter greater than the width of each of the first electrical contact pads 25a, as shown in FIG. 2J. Alternatively, the diameter of each of the first apertures 270a′ is equal to the width of each of the first electrical contact pads 25a, as shown in FIG. 2J′. Alternatively, the first solder mask layer 27a has an aperture 270a″ formed therein for exposing all of the first electrical contact pads 25a, as shown in FIG. 2J″.

The surface treatment layer 28 is formed on the first electrical contact pads 25a.

### Second Embodiment

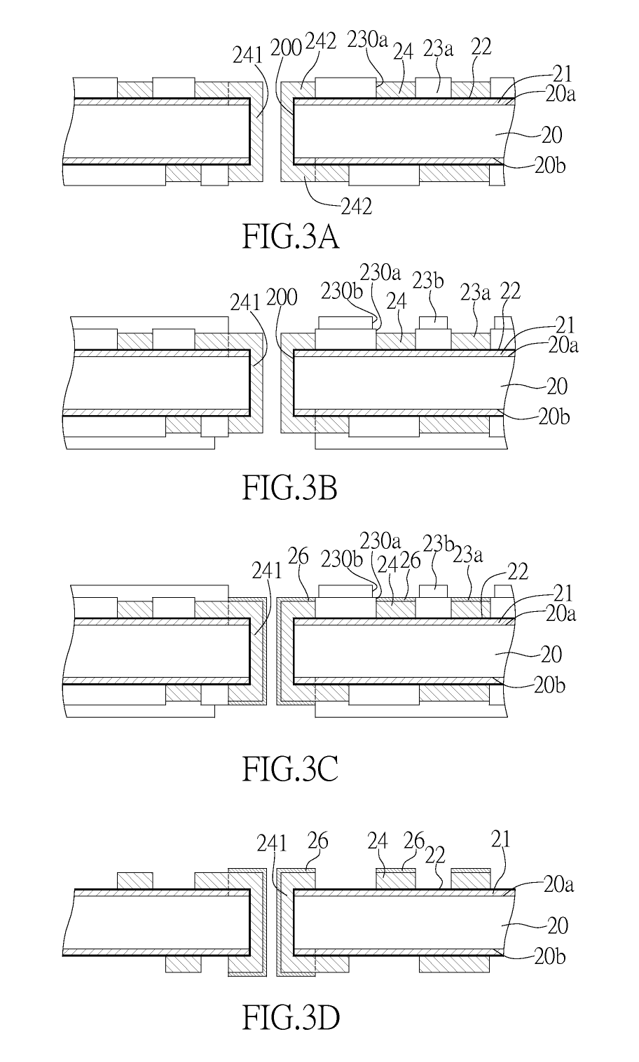

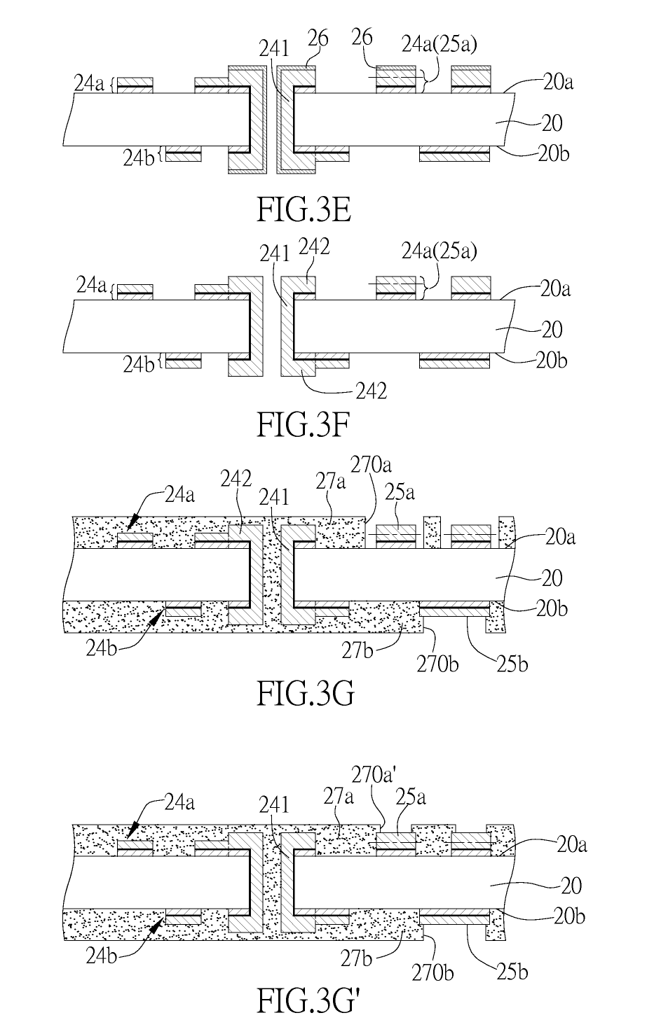

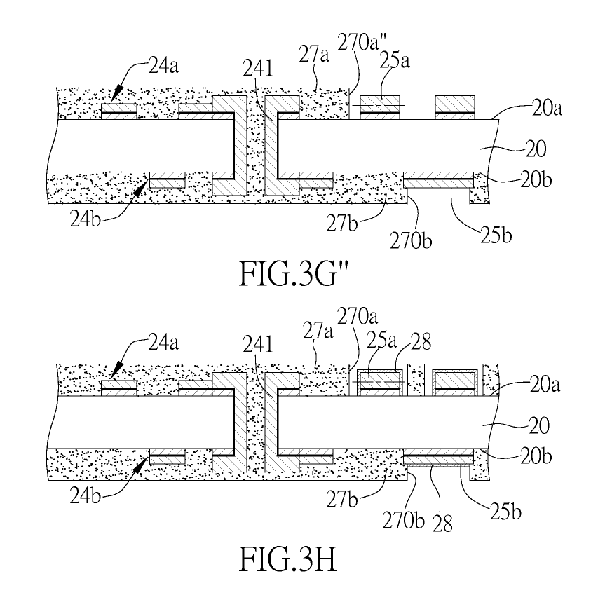

FIGS. 3A to 3H are cross-sectional diagrams showing a package substrate having double-sided circuits and a fabrication method thereof according to a second embodiment of the present invention. The present embodiment is substantially the same with the first embodiment except that, in the present embodiment, an etching stop layer protects a plated through hole.

Referring to FIG. 3A, a structure similar to one shown in FIG. 2D is provided. The second metallic layer 24 is formed in the first opening portions 230a of the first resist layer 23a by plating via the conductive layer 22. Further, the plated through hole 241 is formed in the through-hole 200 by plating a metallic material thereto, and the plated through hole 241 has the connection ring 242 extended to the first surface 20a and the second surface 20b; wherein the through-hole 200 is not fully filled with metal so that the plated through hole 241 is of a hollow shape.

Referring to FIG. 3B, a second resist layer 23b is formed on the second metallic layer 24 and the first resist layer 23a while a plurality of second opening portions 230b are formed in the second resist layer 23b so as to expose a plated through hole 241, a connection ring 242, and a portion of the second metallic layer 24 disposed on the first surface 20a.

Referring to FIG. 3C, an etching stop layer 26 is formed on the exposed portion of the second metallic layer 24, the connection ring 242, and the walls of the plated through hole 241 by plating.

Referring to FIG. 3D, the first resist layer 23a and the second resist layer 23b are removed so as to expose a portion of the second metallic layer 24 and a portion of the conductive layer 22.

Referring to FIG. 3E, the exposed portion of the second metallic layer 24 on the first and second surfaces 20a, 20b are etched to reduce the height of the exposed portion of the second metallic layer 24. Afterward, as shown in the drawing, the conductive layer 22 and the first metallic layer 21 covered with the conductive layer 22 are removed to form on the first and second surfaces 20a, 20b first and second wiring layers 24a, 24b, respectively, electrically connected to the plated through hole 241, to thereby allow the top surface of the connection ring 242 to be higher than that of the first wiring layer 24a. The first wiring layer 24a comprises the first metallic layer 21, the conductive layer 22, and the second metallic layer 24. The second wiring layer 24b comprises the first metallic layer 21, the conductive layer 22, and the second metallic layer 24.

Referring to FIG. 3F, the etching stop layer 26 is removed to form the first electrical contact pads 25a on a portion of the first wiring layer 24a so as to expose the plated through hole 241 therefrom, and thus the top surface of each of the first electrical contact pads 25a is higher than that of the first wiring layer 24a but flush with that of the connection ring 242.

Before forming the wiring layers, it is necessary to form the etching stop layer 26 on the connection ring 242 and a portion of the second metallic layer 24 so as to prevent the connection ring 242 and the portion of the second metallic layer 24 from being etched. Hence, the top surface of the connection ring 242 is higher than that of the first wiring layer 24a. The unetched second metallic layer 24 and the first metallic layer 21 and conductive layer 22 covered by the second metallic layer 24 together function as the first electrical contact pads 25a (at a position of the second metallic layer 24 previously covered with the etching stop layer 26) and thus the top surface of each of the first electrical contact pads 25a is higher than that of the first wiring layer 24a.

Referring to FIG. 3G, a first solder mask layer 27a is formed on the first surface 20a of the core board 20 and the first wiring layer 24a while a second solder mask layer 27b is formed on the second surface 20b of the core board 20 and the second wiring layer 24b. With the plated through hole 241 being of a hollow shape, the plated through hole 241 is filled in full with the first solder mask layer 27a and the second solder mask layers 27b. Further, the first solder mask layer 27a has a plurality of first apertures 270a formed therein for exposing the first electrical contact pads 25a, respectively, and the second solder mask layer 27b has a plurality of second apertures 270b formed therein for exposing a portion of the second wiring layer 24b so as for the exposed portion of the second wiring layer 24b to function as the second electrical contact pads 25b.

In the second embodiment, it is necessary for the connection ring 242 to be covered with the first solder mask layer 27a, and thus the top surface of each of the first electrical contact pads 25a must be lower than the top surface of the first solder mask layer 27a to thereby enable the first apertures 270a to be large enough in diameter to expose the first electrical contact pads 25a therefrom, respectively.

Referring to FIGS. 3G′ along with 3G″, there are various methods for exposing the first electrical contact pads 25a from the first solder mask layer 27a. For example, in FIG. 3G′, the diameter of each of the first apertures 270a′ is less than the width of each of the first electrical contact pads 25a. And FIG. 3G″ shows another example: the first solder mask layer 27a has an opening 270a″ for exposing all of the first electrical contact pads 25a.

Referring to FIG. 3H, a surface treatment layer 28 is formed on the exposed portion of the first wiring layer 24a and each of the first and second electrical contact pads 25a, 25b.

The present invention provides a package substrate having double-sided circuits, comprising: a core board 20 having first and second surfaces 20a, 20b opposing each other; a plated through hole 241 formed in core board 20 to penetrate the core board 20 and the first and second surfaces 20a, 20b and provided with the connection ring 242 extended to the first and second surfaces 20a, 20b; first and second wiring layers 24a, 24b formed on the first and second surfaces 20a, 20b of the core board 20, respectively, and electrically connected to the plated through hole 241, wherein a portion of the first wiring layer 24a has a plurality of first electrical contact pads 25a, allowing the top surface of the first electrical contact pads 25a to be higher than that of the first wiring layer 24a and the top surface of the connection ring 242 to be higher than that of the first wiring layer 24a; the first solder mask layer 27a formed on the first surface 20a of the core board 20 and the first wiring layer 24a so as for the first electrical contact pads 25a to be exposed from the first solder mask layer 27a; and the second solder mask layer 27b formed on the second surface 20b of the core board 20 and the second wiring layer 24b.

The core board 20 is an insulating board. The first wiring layer 24a and the first electrical contact pads 25a are formed from first and second metallic layers 21, 24 and the conductive layer 22. The second wiring layer 24b is formed from the first and second metal layers 21, 24. The plated through hole 241 is of a hollow shape and is filled in full with the first and second solder mask layers 27a, 27b.

The first solder mask layer 27a has a plurality of first apertures 270a, 270a′ formed therein for exposing the first electrical contact pads 25a, respectively; or, alternatively, the first solder mask layer 27a has an aperture 270a″ formed therein for exposing all of the first electrical contact pads 25a. A surface treatment layer 28 is formed on the first electrical contact pads 25a.

The top surface of the first electrical contact pads 25a is flush with the top surface of the connection ring 242.

### Third Embodiment

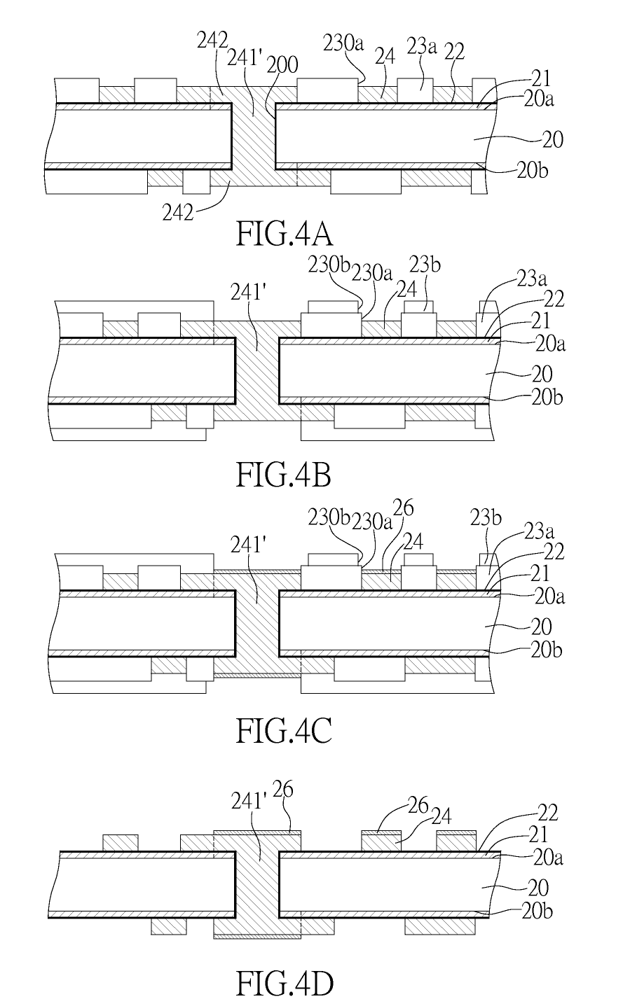

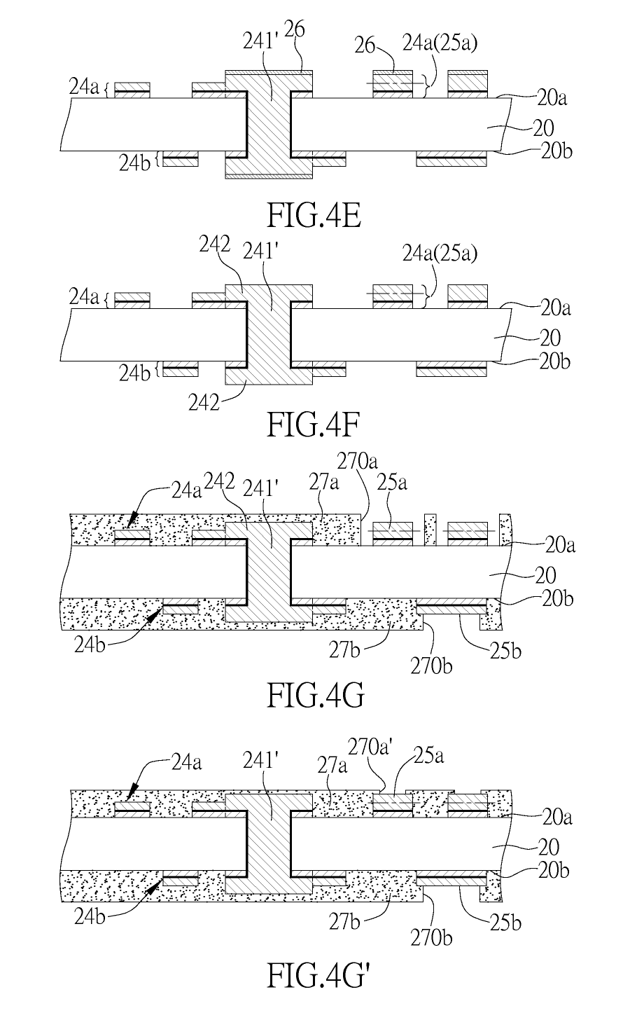

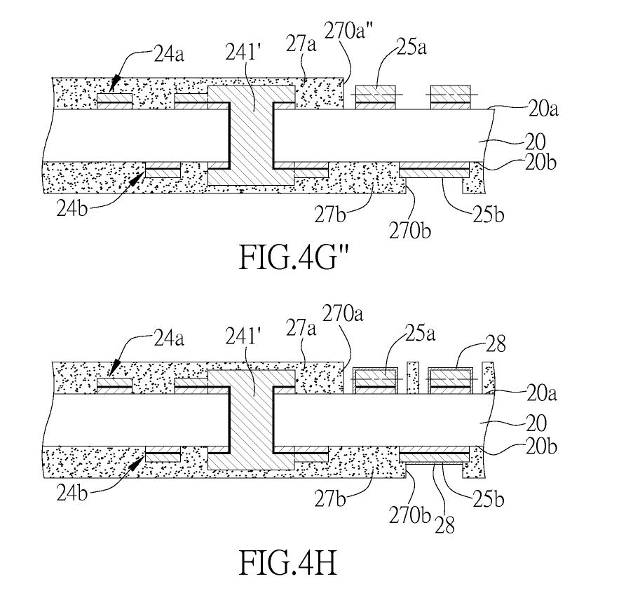

FIGS. 4A to 4H are cross-sectional diagrams showing a package substrate having double-sided circuits and a fabrication method thereof according to a third embodiment of the present invention. The present embodiment is substantially the same with the first and second embodiments except that, in the present embodiment, the plated through hole is of a solid shape and is filled with a metallic material by plating.

Referring to FIG. 4A, a structure similar to FIG. 2D is provided. The second metallic layer 24 is formed in the first opening portions 230a by plating. Further, the through-hole 200 is filled in full with metal by plating a metallic material to the through-hole 200, so that the plated through hole 241′ thus formed is of a solid shape. And the plated through hole 241′ is provided with the connection ring 242 on the first surface 20a and the second surface 20b.

Referring to FIG. 4B, the second resist layer 23b is formed on the second metallic layer 24 and the first resist layer 23a, and the second opening portions 230b are formed in the second resist layer 23b so as to expose the plated through hole 241′, the connection ring 242, and a portion of the second metallic layer 24 on the first surface 20a.

Referring to FIG. 4C, an etching stop layer 26 is formed on the exposed portion of the second metallic layer 24, the connection ring 242, and the walls of the plated through hole 241′ by plating.

Referring to FIG. 4D, the first resist layer 23a and the second resist layer 23b are removed so as to expose a portion of the second metallic layer 24 and a portion of the conductive layer 22.

Referring to FIG. 4E, the exposed portion of the second metallic layer 24 on the first surface 20a and the second surface 20b are etched to reduce the height of the exposed portion of the second metallic layer 24. Further, the conductive layer 22 and the first metallic layer 21 covered with the conductive layer 22 are removed to form the first and second wiring layers 24a, 24b disposed on the first and second surfaces 20a, 20b, respectively, and electrically connected to the plated through hole 241′. The first wiring layer 24a comprises the first metallic layer 21, the conductive layer 22, and the second metallic layer 24. The second wiring layer 24b comprises the first metallic layer 21, the conductive layer 22, and the second metallic layer 24.

Referring to FIG. 4F, the etching stop layer 26 is removed to form the plurality of first electrical contact pads 25a and expose the plated through hole 241′ and the connection ring 242, wherein the top surface of each of the first electrical contact pads 25a is higher than that of the first wiring layer 24a.

Forming the wiring layers is preceded by forming the etching stop layer 26 on the connection ring 242 and a portion of the second metallic layer 24 so as to prevent the connection ring 242 and a portion of the second metallic layer 24 from being etched to thereby allow the top surface of the connection ring 242 to be higher than the top surface of the first wiring layer 24a and allow the unetched second metallic layer 24 and the underlying first metallic layer 21 and conductive layer 22 to function as the first electrical contact pads 25a (that is, at the position of the second metallic layer 24 previously covered with etching stop layer 26). Hence, the top surface of the first electrical contact pads 25a is higher than the top surface of the first wiring layer 24a.

Referring to FIG. 4G, the first solder mask layer 27a is formed on the first surface 20a of the core board 20 and the first wiring layer 24a while the second solder mask layer 27b is formed on the second surface 20b of the core board 20 and the second wiring layer 24b. Further, the first solder mask layer 27a has a plurality of first apertures 270a formed therein for exposing the first electrical contact pads 25a, respectively, and the second solder mask layer 27b has a plurality of second apertures 270b formed therein for exposing a portion of the second wiring layer 24b so as for the exposed portion of the second wiring layer 24b to function as the second electrical contact pads 25b.

Referring to FIGS. 4G′ and 4G″, there are various methods for exposing the first electrical contact pads 25a from the first solder mask layer 27a. In the third embodiment, the diameter of each of the first apertures 270a is configured to effect the exposure of each of the first electrical contact pads 25a. Thus, in FIG. 4G′, the diameter of each of the first apertures 270a is less than the width of each of the first electrical contact pads 25a. Referring to FIG. 4G″, the first solder mask layer 27a has an aperture 270a″ formed therein for exposing all of the first electrical contact pads 25a.

Referring to FIG. 4H, a surface treatment layer 28 is formed on the exposed first wiring layer 24a and each of the first and second electrical contact pads 25a, 25b.

According to the present invention, the etching stop layer 26 prevents the first electrical contact pads 25a from being etched and thinned down and thereby allows the top surface of the first electrical contact pads 25a to be higher than that of the first wiring layer 24a. In contrast to prior art, the present invention provides the first electrical contact pads 25a formed to have a top surface thereof high enough for the first electrical contact pads 25a to replace solder bumps so as for the present invention to dispense with solder bumps; hence, the semiconductor chip of the present invention is readily flip-chip mounted on the first electrical contact pads 25a.

In conclusion, a package substrate having double-sided circuits and a fabrication method thereof are provided by the present invention. In contrast to prior art, the present invention provides a plurality of first electrical contact pads formed to replace solder bumps so that the present invention dispenses with solder bumps. Moreover, the average values and allowable tolerances in volume and height of the first electrical contact pads are better controllable, so as to avoid an otherwise difficult job of filling the underfill, bridging of contacts, and an unbalanced contact stress due to poor coplanarity, thereby achieving an increased layout density and enhancing the electrical connection yield. Also, an etching stop layer is formed on a plated through hole; or instead, a plated through hole assumes a solid shape by plating a metallic material to the through-hole. In so doing, it is feasible to avoid an insufficient thickness of a plated through hole which might otherwise be the case when etching the plated through hole.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A package substrate having double-sided circuits, comprising:
a core board having a first surface, an opposing second surface, and a plated through hole, the plated through hole penetrating the first and second surfaces and having a connection ring extending to the first and second surfaces;
first and second wiring layers formed on the first surface and the second surface of the core board, respectively, and electrically connected to the plated through hole;
a plurality of first electrical contact pads disposed on a top surface of a portion of the first wiring layer, allowing a top surface of the first electrical contact pads to be higher than the top surface of the portion of the first wiring layer, wherein the top surface of the portion of the first wiring layer having the first electrical contact pads disposed thereon is higher than the top surface of the portion of the first wiring layer not having the first electrical contact pads disposed thereon;
a first solder mask layer formed on the first surface of the core board and the first wiring layer to thereby allow the first electrical contact pads to be exposed from the first solder mask layer; and
a second solder mask layer formed on the second surface of the core board and the second wiring layer.

2. The package substrate of claim 1, wherein the core board is an insulating board.

3. The package substrate of claim 1, wherein the first solder mask layer has a plurality of first apertures for exposing the first electrical contact pads, respectively.

4. The package substrate of claim 3, wherein a diameter of the first apertures is larger than or equal to a width of each of the first electrical contact pads.

5. The package substrate of claim 1, wherein a top surface of the first solder mask layer is lower than the top surface of the first electrical contact pads.

6. The package substrate of claim 1, wherein the first solder mask layer has an opening for exposing the first electrical contact pads.

7. The package substrate of claim 1, wherein a surface treatment layer is disposed on the first electrical contact pads.

8. The package substrate of claim 1, wherein the plated through hole is of a hollow shape and is filled in full with the first and second solder mask layers.

9. The package substrate of claim 1, wherein the plated through hole is of a solid shape and is filled in full with a metallic material by plating.

10. The package substrate of claim 1, wherein a top surface of the connection ring is flush with the top surface of the first wiring layer not having the first electrical contact pads disposed thereon.

11. The package substrate of claim 1, wherein the first wiring layer comprises first and second metallic layers, and the second wiring layer comprises the first and second metallic layers, allowing the first electrical contact pads to be disposed on the second metallic layer.

12. A package substrate having double-sided circuits, comprising:
a core board having a first surface, an opposing second surface, and a plated through hole, the plated through hole penetrating the first and second surfaces and having a connection ring extending to the first and second surfaces;
first and second wiring layers formed on the first surface and the second surface of the core board, respectively, and electrically connected to the plated through hole, wherein a portion of the first wiring layer has a plurality of first electrical contact pads disposed thereon, allowing a top surface of the first electrical contact pad to be higher than a top surface of the first wiring layer and a top surface of the connection ring to be higher than the top surface of the first wiring layer;
a first solder mask layer formed on the first surface of the core board and the first wiring layer so as for the first electrical contact pads to be exposed from the first solder mask layer; and
a second solder mask layer formed on the second surface of the core board and the second wiring layer.

13. The package substrate of claim 12, wherein the core board is an insulating board.

14. The package substrate of claim 12, wherein the first solder mask layer has a plurality of first apertures for exposing the first electrical contact pads, respectively.

15. The package substrate of claim 12, wherein the first solder mask layer has an opening for exposing the first electrical contact pads.

16. The package substrate of claim 12, wherein the top surface of the first electrical contact pads is flush with the top surface of the connection ring.

17. The package substrate of claim 12, wherein a surface treatment layer is disposed on the first electrical contact pads.

18. The package substrate of claim 12, wherein the plated through hole is of a hollow shape and is filled in full with the first and second solder mask layers.

19. The package substrate of claim 12, wherein the plated through hole is of a solid shape and is filled in full with a metallic material by plating.

20. The package substrate of claim 12, wherein the first wiring layer and the first electrical contact pads are formed from first and second metallic layers, and the second wiring layer is formed from the first and second metallic layers.
